(19) United States
(12) Patent Application Publication
(10) Pub. No.: US 2012/0068196 A1
(43) Pub. Date: Mar. 22, 2012

(54) SEMICONDUCTOR LIGHT-EMITTING DEVICE AND A METHOD OF MANUFACTURE THEREOF

(75) Inventors: Tim Michael SMEETON, Oxford (GB); Mathieu Xavier SENES, Oxford (GB); Wei-Sin TAN, Oxford (GB); Valerie BERRYMAN-BOUSQUET, Oxford (GB)

(73) Assignee: SHARP KABUSHIKI KAISHA, Osaka (JP)

(21) Appl. No.: 13/228,648

(22) Filed: Sep. 9, 2011

(30) Foreign Application Priority Data
Sep. 16, 2010 (GB) 1015518.2

(51) Int. Cl. H01L 33/20; H01L 33/00

(52) U.S. Cl. 257/79; 438/42; 257/E33.006; 257/E33.012

(57) ABSTRACT

A semiconductor light-emitting device comprises a semiconductor layer structure disposed over a substrate. The layer structure includes an active region disposed between a first layer and a second layer. One or more cavities are present in the layer structure, each cavity being coincident with a threading dislocation and extending from an upper surface of the layer structure through at least the second layer and the active region. Removing material where a threading dislocation is present provides effective suppression of the tendency of the threading dislocations to act as non-radiative centres, thereby improving the light output efficiency of the device. The device may be manufactured by a first step of selectively etching the layer structure at the locations of one or more threading dislocation to form a pilot cavity at the or each location. A second etching step is applied to increase the depth of each pilot cavity.

This Nonprovisional application claims priority under 35 U.S.C. §119(a) on Patent Applications No. 1015518.2 filed in U.K. on Sep. 16, 2010, the entire contents of which are hereby incorporated by reference.

### FIELD OF THE INVENTION

The present invention relates to the field of a semiconductor light emitting device with reduced defect density, and more specifically of a semiconductor light emitting device such as, for example, a light emitting diode, where defects are removed from the p-n junction and active region, thus leading to high light output efficiency. It also relates to a method of manufacturing such a semiconductor light emitting device

### BACKGROUND OF THE INVENTION

Light emitting diodes (LEDs) and other semiconductor light emitting devices such as laser diodes are key components to a wide range of applications that include backlighting units for liquid crystal displays, headlamps for automobiles, or general lighting. For example nitride semiconductor based blue- and green-emitting LEDs (that is, LEDs emitting at wavelengths in the blue or green regions of the spectrum) are widely used in these applications. However, the performance of such LEDs can be seriously degraded by the presence of threading dislocations as they can act as non-radiative centres. These threading dislocations are linear defects in the LED crystal passing all the way through the device structure. Nitride based LEDs which are deposited on non native substrate (such as for example sapphire, silicon, silicon carbide . . . ) commonly exhibit a high density per unit area of threading dislocations, typically around 10⁸-10⁹ cm⁻². Therefore, it is desirable to reduce threading dislocation density within the LED structure or to minimize their effect to improve the light output efficiency.

A prior approach for reducing the defect density in LEDs is the use of substrates with lower dislocation densities such as free-standing GaN (see X. A. Cao et al., Appl. Phys. Lett. 84, 4313, 2004) or substrates grown using the Epitaxial Layer Overgrowth (ELOG) method (see US patent publication 2002/0022290). The defect density in ELOG substrate or in free-standing GaN substrates can be reduced down to 10⁵-10⁶ cm⁻². However such substrates are currently very expensive and not available in large wafer size. These approaches are therefore not suitable for large scale use.

A second approach, described in U.S. Pat. No. 7,399,684, is to prepare low defect density substrates where the defects have been removed using a preferential etching method. The method consists of growing a layer of epitaxial material on the substrate, then performing an ex-situ etching of the whole surface of the substrate in such a manner as to preferentially etch the defects of the layer, and finally grow a subsequent layer of epitaxial material on the etched epitaxial layer and the substrate to form LED structure over the substrate. However, this method requires a user to stop the epitaxial growth of the LED, to remove the LED wafer from the growth chamber and to perform the etching step. The etched wafer is then returned to the growth chamber and the growth process is restarted. This is time-consuming and it is not desirable to stop the growth of the LED as it can introduce new defects during the growth of the subsequent layer.

A third approach to reduce the effects of threading dislocations, described by T. Y. Park et al. in Electrochemical and Solid-state Letters, 12 (1) D3-D6 (2009), is to use chemical etching of the upper surface of the LED, eg the p-GaN surface, to neutralise the effects of deep donor-acceptor pair near the surface region. The authors report a decrease of the defect-assisted leakage currents at the forward and reverse bias voltage, and an improved light output power due to enhanced injection efficiency. However, the defects are only removed at the surface of the LED, and then are still present inside the LED, especially in the quantum well active region. Therefore, the radiative recombination efficiency is still greatly affected by the presence of the defects.

Another approach, described by Z. Fang et al. in Journal of Applied Physics 106, 023517 (2009), consists of using an in situ selective etching step during the epitaxial growth to etch pits around dislocations in InGaN quantum wells. The advantage of this method is an increase of the luminescence efficiency as reported by the authors. However, this in situ etching technique does not reduce the dislocation density in the epitaxial layers above the active region, and adds complex steps to the epitaxial growth of the LED.

Finally, a last approach would consist of preventing the carriers to reach areas containing a threading dislocation defect instead of reducing the defect density of the LED structure. For example an approach, described by M. Y. Hsieh et al. in IEEE journal of quantum electronics vol. 44, no. 5, May 2008, is to fabricate InGaN-GaN multiple quantum well nanorod structures in the LED. The method consists of depositing a nanoparticle mask on top of the LED, then etching the sample through the active region using a dry etching process to form nanorods. The size of the nanorods is around 600 nm height and 100 nm diameter. The advantage of this invention is the extra confinement of the carriers in the quantum well active region provided by the nanorods, so the carriers are less likely to move to an area of the active region containing a defect and then recombine non-radiatively. However, making the nanorods requires to remove a significant part of the LED area, leading to a reduction in the active region area and consequently in the total light output intensity. Threading dislocations may still be present in a proportion of the nanorods as nanorods location is not aligned to dislocation position at the top of the LED.

US 2009/0029493 relates to the presence of dislocation defects in a light-emitting device, and refers to “pits” associated with a dislocation. It proposes opening the pits, by providing a suitable “pit opening layer”. The active region of the device is then grown over the “pit opening layer”, so that the layers of the active region can extend into the open pit.

US 2006/019209 proposes growing a layer structure over a substrate, and then forming a “groove” in the structure at a region where the substrate has a high average dislocation density, so that a device is present only at regions of the substrate that have a low average dislocation density.

U.S. Pat. No. 6,329,667 proposes removing material at the site of a defect during the growth of a layer structure. The structure is removed from the growth reactor after the active layer is grown, to enable the active layer to be etched to faun a recess or pit. After the etching process, the substrate is then returned to the growth reactor for the growth of the subsequent layers. This method suffers from the disadvantages set out above in connection with U.S. Pat. No. 7,399,684.

EP 1,267,422 proposes a method that is generally similar to the method proposed in U.S. Pat. No. 6,329,667, and that again requires that the growth process is interrupted to allow the part-grown structure to be etched at dislocation sites. Compared to U.S. Pat. No. 6,329,667, EP 1,267,422 further proposes growing a low temperature AlGaN barrier layer 71 over the active layer before removing the part-grown structure for etching, to prevent the InGaN layer deteriorating when the device structure is returned to the reactor after etching. This method also suffers from the disadvantages set out above in connection with U.S. Pat. No. 7,399,684.

### SUMMARY OF THE INVENTION

A first aspect of the invention provides a semiconductor light-emitting device comprising: a substrate; a semiconductor layer structure disposed over the substrate and including a first layer disposed over the substrate, a second layer, and an active region for light emission disposed between the first layer and the second layer; and one or more cavities in the layer structure, the or each cavity being coincident with a respective threading dislocation of at least a first type that extends generally through the layer structure, and the or each cavity extending from an upper surface of the layer structure through at least the second layer and the active region.

Since the cavities extend through the active region, and accordingly through the layer(s) of the layer structure above the active region (where a layer that is “above” the active region is on the opposite side of the active region to the substrate), the invention provides a much more effective suppression of the tendency of the threading dislocations to act as non-radiative centres than do the prior art approaches in which the defects are removed only at the surface of the device or only at the active region, thereby leading to a light emitting device that exhibits improved light emission efficiency.

A second aspect of the invention provides a method of manufacturing a semiconductor light-emitting device having a semiconductor layer structure disposed on a substrate, the layer structure including a first layer disposed over the substrate, a second layer, and an active region for light emission disposed between the first layer and the second layer, the method comprising:
selectively removing material from the layer structure at one or more locations at which a respective threading dislocation of at least a first type is present in the layer structure so as to create a cavity in the layer structure, the cavity extending at least through the second layer and the active region.

As explained above, by forming cavities that extend through the active region, and accordingly through the layer(s) of the layer structure above the active region (where a layer that is “above” the active region is on the opposite side of the active region to the substrate), the invention provides a much more effective suppression of the tendency of the threading dislocations to act as non-radiative centres than do the prior art approaches in which the defects are removed only at the surface of the device or only at the active region, thereby leading to a light emitting device that exhibits improved light emission efficiency.

According to the invention, material is removed from the semiconductor layer structure after growth of the semiconductor layer structure is completed. There is therefore no need to interrupt and re-start an epitaxial growth process as in the methods proposed in U.S. Pat. No. 7,399,684 or by Fang et al. (above). In principle, the only required processing steps after formation of the cavities in the layer structure are the deposition of electrodes and the dicing of the wafer into individual devices (and in certain preferred embodiments to be described below the deposition of an electrode layer may be combined with the creation of the cavities in the layer structure).

A third aspect of the invention provides a semiconductor light-emitting device formed by a method of the second aspect. A device of the third aspect may for example comprise a light-emitting diode, or a laser diode.

The present invention describes a semiconductor light emitting device wherein threading dislocations are removed from p-n junction and active region, and thus exhibits high light output efficiency. The invention thus addresses the above problems by providing a LED with high efficiency where a significant proportion of the defects have been removed.

According to one aspect of the invention, threading dislocations are removed by a combination of wet etching and dry etching.

According to another aspect, the light emitting diode is fabricated in the (Al,In,Ga)N material system.

The foregoing and other objectives, features, and advantages of the invention will be more readily understood upon consideration of the following detailed description of the invention, taken in conjunction with the accompanying drawings.

### BRIEF DESCRIPTION OF THE DRAWINGS

Preferred embodiments of the present invention will now be described by way of illustrative example with reference to the accompanying drawings in which:

FIG. 1 is a sectional view showing a nitride light emitting diode where the threading dislocations are removed from the active region and p-n junction according to a first embodiment of the invention.

FIG. 2 is a top view of the light emitting diode according to a first embodiment of the invention. The areas where the threading dislocations have been removed are visible on the top p-electrode and exhibit hexagonal shape.

FIG. 3 is a flowchart that illustrates the processing steps used in the preferred embodiment of the present invention.

FIGS. 4(a)-4(f) further illustrate the LED structure schematic after each processing steps of FIG. 3.

FIGS. 5(a)-5(c) illustrate principal steps in a fabrication method according to another embodiment of the present invention

### DESCRIPTION OF EMBODIMENTS

Preferred embodiments of the invention relating to manufacture of an LED will be described by way of example. However, the invention is not limited to use with an LED and may be applied to other semiconductor light-emitting devices such as laser diodes.

A device of the present invention may be grown by any suitable means and on any suitable substrate, which include but is not limited to any orientation of: sapphire, GaN or SiC. A preferred growth method may be MOVPE (metal organic vapour phase epitaxy), but any other suitable growth method such as, for example, HVPE (hybrid vapour phase epitaxy) or MBE (molecular beam epitaxy) may be used.

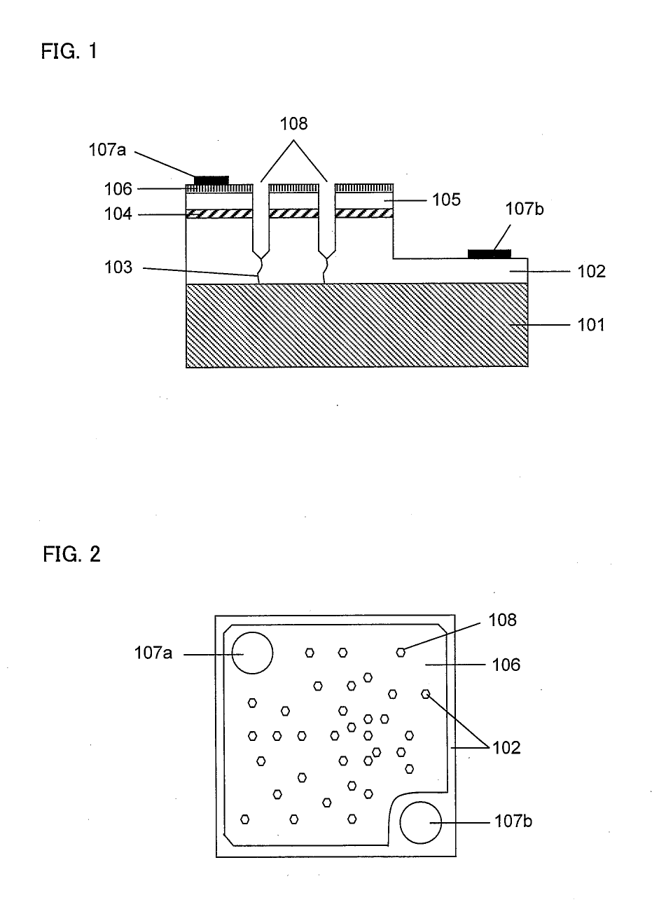

A light-emitting device according to a first embodiment of the present invention is described with reference to FIG. 1. FIG. 1 shows a schematic cross-section through a light emitting diode fabricated in the (Al,In,Ga)N material system where the threading dislocations have, according to the present invention, been removed from the p-n junction and active region of the device. The light emitting diode of FIG. 1 contains a substrate 101 which may for example be a sapphire substrate 101. A semiconductor layer structure formed of a plurality of semiconductor layers is provided on the substrate 101. In the example of FIG. 1, the layer structure consists of a first layer 102 disposed over the substrate 101, an active region 104 having one or more layers and disposed over the first layer 102, and a second layer 105 disposed over the active region 104. The first layer and the second layer are generally of opposite conductivity type so that a p-n junction is set up in the device structure.

In more detail, in the device of FIG. 1 the first layer 102 is an n-type layer 102 made in the (Al,Ga,In)N materials system and is disposed on top of the substrate 101. The active region 104 is disposed on top of the layer 102. The second layer 105 is a p-type (Al,Ga,In)N layer 105 disposed over part of the active region 104. On the top surface of the layer 105 is a p-electrode 106, which may be composed of multiple layers. On top of the p-electrode 106 is a p-type pad electrode 107a, and an n-type pad electrode 107b is provided on a part of the surface of the layer 102 where the active region 104 is not present. (By an “(Al,Ga,In)N layer” or “a layer in the (Al,Ga,In)N materials system” is meant a layer having the general formula where 0≦x≦1, 0≦y≦1, 0≦z≦1 and x+y+z=1.)

The thickness and composition of the n-type layer 102, active region 104 and the p-type layer 105 may be conventional, and will not be described in detail. Also the invention is not limited to use with a device having the exact structure shown in FIG. 1 and the device structure may include other layers such as, for example and without limitation, a buffer layer disposed between the substrate 101 and the first layer 102 and/or a capping layer over the second layer 105.

The light emitting diode structure is likely to contain a high density of threading dislocations 103. For example, the density of threading dislocation in light emitting diodes grown on sapphire substrates is typically around 10⁸-10⁹ cm⁻². Moreover, three different types of dislocations can be distinguished: pure screw dislocations, which account for around 10-20% of total dislocations, mixed dislocations, which account for about 30% of total dislocations, and pure edge dislocations, which account for about 50% of total dislocations (see as a reference the article of U. Jahn et al. published in Physical Review B 81, 125314, 2010). However, the percentages of the different types of dislocations given previously may vary, and are only given here as an example.

The invention does not however require that the device structure contains any particular density of dislocations. As an example, in another embodiment of the present invention, the light emitting diode structure may contain a density of threading dislocations less than 10⁸ cm⁻².

According to the invention, the threading dislocations 103 (or, as described in more detail below, the threading dislocations 103 of at least a first type) present in the active region 104 and in the p-n junction comprising the p-type layer 105 and part of the n-type layer 102 are removed by mean of a preferential etching to give respective etched areas 108 (or “cavities”) which extend from the upper surface of the device structure at least through the active region 104 and preferably through part of the n-type layer 102 that is the lower layer of the p-n junction of the device. This is shown in FIG. 1. Indeed, although not shown in FIG. 1 some or all of the etched areas or cavities 108 could extend through the entire thickness of the n-type layer 102 and into the substrate. (The terms “upper” and “lower” as used herein relate to a device oriented as shown in FIG. 1, so that the “upper” surface of the device is the surface of the device that is furthest from the substrate; however, use of the teens “upper” and “lower” does not mean that the invention requires that the devices are oriented as shown in FIG. 1.)

FIG. 2 is a top view of the light-emitting device of FIG. 1, where the etched areas 108 are represented. The etched areas can be of any size, but the preferred diameter of an etched area 108 is between 100 nm and 2000 nm. The depth of the etched areas is typically around 300-700 nm or any other suitable dimension such that the bottom of the etched areas extends into the n-type layer 102.

FIG. 1 shows by way of example two threading dislocations 103 in the device structure, both of which of are removed to give etched areas 108 that extend through the device structure into the n-type layer 102. The typical density of threading dislocations present in an actual device means that it may not be possible to remove every threading dislocation in a device structure in this way. Thus, in a second embodiment, more than 1% of the threading dislocations present in the active region and p-n junction are removed, so the light emitting device exhibits improved light emission efficiency. Preferably, more than 10% of all of the threading dislocations are removed, and particularly preferably all or substantially all the threading dislocations are removed.

Mention is next made of one of the possible options of processing steps for the fabrication of the present invention.

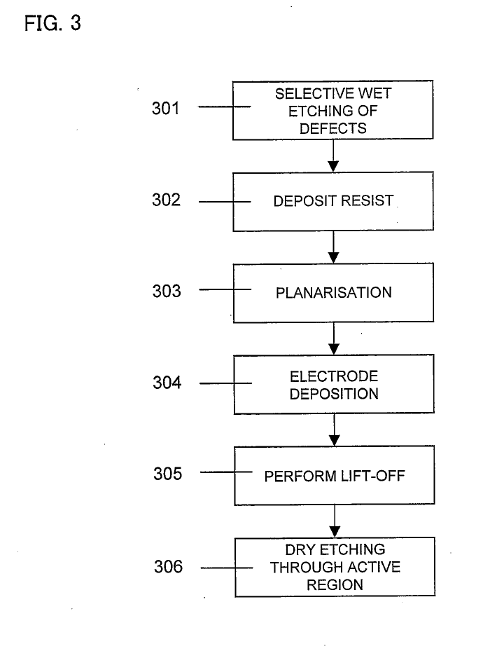

FIG. 3 is a flowchart that illustrates the processing steps used in a fabrication method according to one embodiment of the present invention.

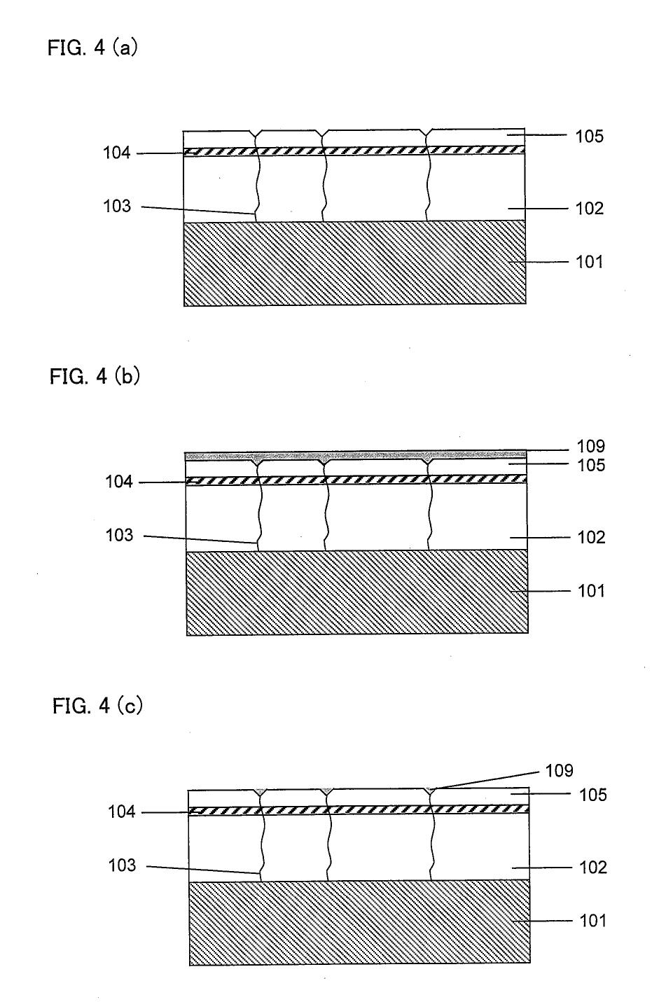

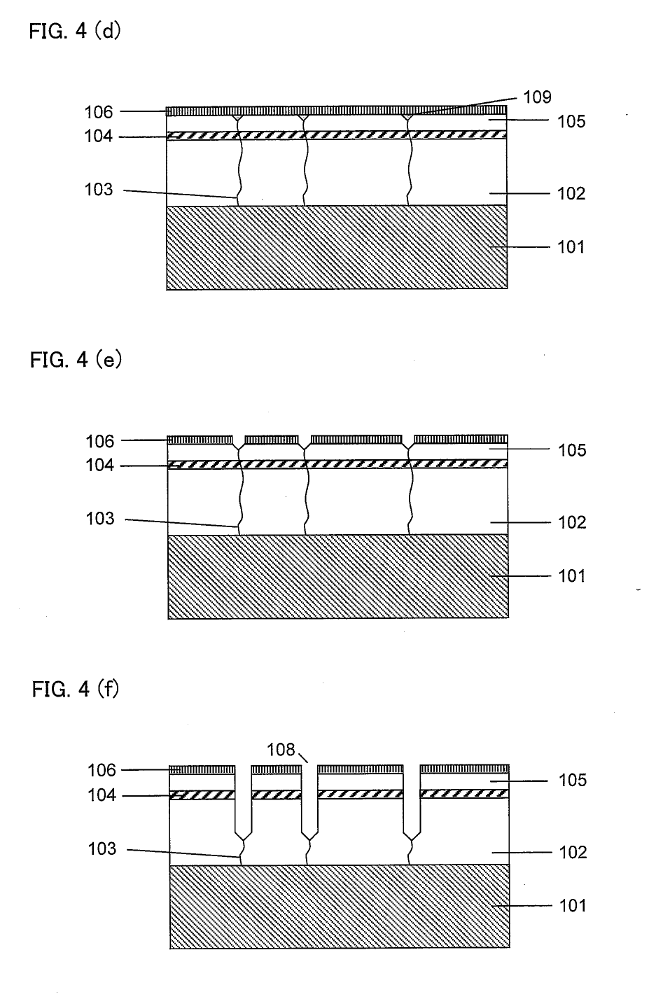

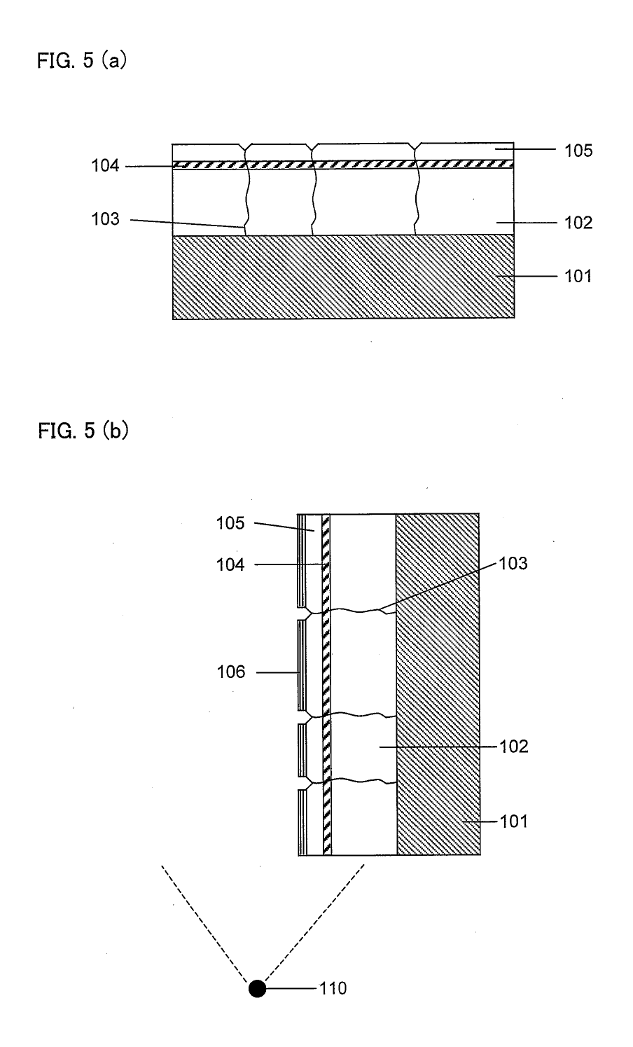

Block 301 represents the step of the selective etching of the defects at the surface of the p-type layer 105 of the device structure in FIG. 1 (as explained below, the electrode 106 or the electrode pad 107a have not yet been formed). The etching of block 301 acts preferentially on the epitaxial layer 105 in FIG. 1 at the defects, so that a pilot cavity is formed at the site of each threading dislocation. A “pilot” cavity is formed at location where it is desired to provide an etched area or cavity 108 (ie, is formed where a dislocation is present). It is referred to as a “pilot” cavity as its depth is much less than the desired depth of an etched area or cavity 108 (in the example of FIG. 4(a), for example, a “pilot” cavity does not extend into the active region 104 but is wholly contained within the p-type layer 5. As will become apparent from the description below, after a pilot cavity has been formed it is increased in depth to form an etched area or cavity 108 that extends at least through the active region 104.

In the present embodiment, the preferential etching is performed by immersion in molten KOH, or aqua regia (which is a solution composed of hydrochloric acid and nitric acid), or a mixture of KOH/NaOH, or H₃PO₃ or any other suitable wet etching solution. Alternatively, the preferential etching may be performed by exposing the surface of the p-type layer 105 to dry etching by RIE (reactive ion etching), or ICP (inductively coupled plasma etching), or chemically assisted ion beam etching, or other suitable dry etching process.

Block 302 represents the step of depositing resist layer on top of the sample. The resist may include, but is not limited to, PMMA or any other materials suitable for lift-off process.

Block 303 represents the step of the planarisation of the resist layer. This step consists of removing the resist from the surface of the top p-type layer 105 in FIG. 1. The resist can be removed by dry etching using RIE or ICP, or by any other suitable methods. Thus, after planarisation of the resist layer only the pilot cavities made by the preferential etching processing step detailed in Block 301 are filled with resist.

Block 304 represents the step of depositing the p-electrode 106 of FIG. 1. The p-electrode 106 can be, but is not limited to, a transparent current spreading layer like indium tin oxide, or non transparent metal contact as nickel-gold or titanium-gold.

Block 305 represents the step of performing a lift-off process. The lift-off process can be performed by using acetone in an ultra-sonic bath, or by any other suitable methods. As a result of block 305, the portions of the p-electrode located above the cavities containing the lift-off resist are removed.

Block 306 represents the step of performing further etching, for example dry etching, so that each pilot cavity formed by the etching of Block 301 is increased in depth so as to form a cavity 108 that extends through p-type layer 105, through the active region, and into the n-type layer 102. This step thus constitutes selectively removing material from the device structure at one or more locations at which a respective threading dislocation is present (since the pilot cavities were formed in Block 301 at the site of threading dislocations). In the present embodiment, the dry etching is performed by exposing the surface to dry etching by ICP or RIE, or other suitable dry etching process. Moreover, in the present embodiment, the p-electrode 106 is used as a mask when performing the dry etching process.

FIGS. 4(a)-4(f) further illustrate steps in the fabrication of a light-emitting device, in this example an LED, according to the method of FIG. 3. Specifically, FIG. 4(a) shows the LED structure after Block 301 of preferentially etching the defects at the surface of the p-type layer 105 to form the pilot cavities. FIG. 4(b) shows the structure after the deposition of the resist at Block 302. FIG. 4(c) shows the results after the planarisation process of Block 303, where the resist 109 is only left in the pilot cavities made by the preferential etching process. FIG. 4(d) shows the structure after the deposition of the p-electrode layer 106 at block 304. FIG. 4(e) shows the results after the lift-off process at Block 305. FIG. 4(f) shows the structure after the dry etching step to increase the depth of the pilot cavities to form etched areas or cavities 108 that extend at least through the active region 104 at Block 306.

It will be understood that the invention is not limited to the exact method shown in FIG. 3 and FIGS. 4(a)-4(f). As an example, in a case where a capping layer is present in the device structure over the p-type layer 105, both the capping layer and the p-type layer 105 may be etched by the first etch step, provided that the capping layer is susceptible to etching. For example where a capping layer of a semiconductor material is present over the p-type layer 105, then the etching may be performed as described with both the capping layer and the p-type layer 105 being etched in the first etch step 301 such that the pilot cavities extend through the capping layer 105 and into the p-type layer 105. Alternatively the first etching step may etch only the capping layer or part of the capping layer such that the pilot cavities extend only into the capping layer, so that the p-type layer 105 is not etched until the second etch step.

In another embodiment, another material different to the p-electrode can also be deposited as the hard mask used for the dry-etching process. In this case, the sequence shown in FIGS. 4(b)-4(e) is repeated again but with another material (i.e. SiO₂) deposited on top of the p-electrode. For example, the steps of FIGS. 4(b)-4(e) may be repeated, so that there are two lift-off processes (the first one to pattern the p-electrode, and the second one to pattern the SiO₂ to form a mask for the second etching step of FIG. 4(f)). Alternatively, only one lift-off step may be used even when another material different to the p-electrode is deposited as a hard mask for the dry-etching process—in this case both the additional mask and the p-electrode would be removed during the lift off step (to summarise, the steps would be deposit resist, planarise the resist, deposit the p-electrode material, deposit the mask material, perform the lift-off, and then perform the second etch). A yet further option could be to deposit the p-electrode material, deposit the resist, planarise, deposit the mask material, perform lift off to pattern the mask material, and then perform the second etch—so that the patterned mask is used to etch both the p-electrode and the layer structure.

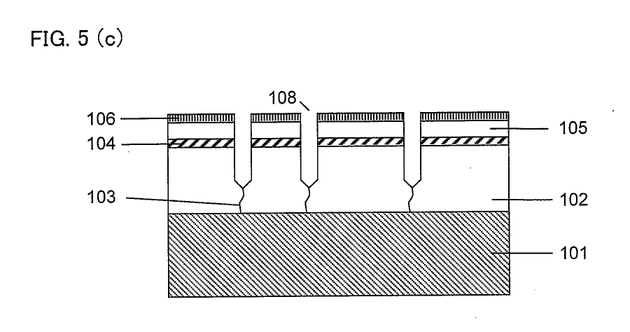

In another embodiment of the present invention, the fabrication steps illustrated in FIG. 4(b), FIG. 4(c) and FIG. 4(d) may be avoided by depositing the p-electrode directly on the LED such that no (or little) electrode material is deposited in the etched areas 108. This may be effected by, for example, mounting the LED structure in a thermal evaporator such that the surface of the structure on which the p-electrode is to be deposited is substantially parallel to the direction along which the p-electrode material is deposited. Principal steps of a fabrication process according to this embodiment are illustrated in FIGS. 5(a)-5(c). FIG. 5(a) shows the LED structure after the preferentially etching of the defects at the surface of the p-type layer 105, and so corresponds generally to FIG. 4(a). FIG. 5(b) shows the LED structure mounted in a thermal evaporator such that the growth surface is at an oblique angle or even parallel to the general direction of material deposition from a source 110 (the LED structure may be oriented at 90 degrees (or any other suitable angle) to its orientation for preferential etching of the defects in FIG. 5(a)). As a result when the material used for making the p-electrode layer 106 is evaporated it is then deposited on the surface of the LED structure but not in the etched holes made in the surface of the LED structure in FIG. 5(a). It can be seen that the structure of FIG. 5(b) corresponds generally to that of FIG. 4(e), in that the p-electrode material is not present where the p-layer 105 was etched in FIG. 4(a) or FIG. 5(a)—but the method of FIGS. 5(a)-5(c) uses selective deposition of the electrode material whereas the method of FIGS. 5(a)-5(c) deposits the electrode material over the entire upper surface of the device structure and then removes the electrode material from selected areas.

Finally, FIG. 5(c) shows the structure after the dry etching through the active region 104, and it can be seen that this corresponds to the structure of FIG. 4(f).

In another embodiment of the present invention, LED mesas can be formed using photolithography and ICP etching, or any other suitable methods, in order to deposit the n-type pad electrode 107b on the n-type layer 102 as shown in FIG. 1 or FIG. 2.

Moreover, in another embodiment of the present invention, the sample may need further processing steps in order to reduce junction leakage and non-radiative recombination due to the presence of surface states and plasma-induced defects (for further details about surface states and plasma-induced defects, see the articles of H. S. Yang et al. in Applied Physics Letters 86, 102104, 2005 and H. M. Kim et al. in Electrochemical Solid State Letters 7, G241, 2004). The further processing steps can for example consist of a thermal annealing of the sample under nitrogen, or any other suitable methods (see for example the article of Y. Yang et al. published in Applied Physics Letters 95, 011109, 2009 for some examples of methods which suppress surface leakage currents).

In another embodiment of the present invention, the cavities 108 of FIG. 1 can be filled with an electrically non-conductive material, or with a combination of electrically non-conductive layers. The electrically non-conductive layer(s) can be, but are not limited to, a dielectric material such as silica or spin-on-glass, or a phosphor or nanophosphor material made of, for example, cerium-doped yttrium aluminium garnet, SiAlON, cadmium selenide, cadmium sulfide, (In,Ga)N or indium phosphide.

Although the invention has been described with respect to certain preferred embodiments, it is obvious that equivalents and modifications will occur to others skilled in the art upon the reading and understanding of the specification. The present invention includes all such equivalents and modifications, and is limited only by the scope of the following claims.

For example, while the invention has been described with reference to fabrication of light-emitting devices in the (Al,In,Ga)N materials system, the invention is not limited to this and may be applied to other material systems.

As a further example, the invention is not limited to the two-stage etching process described with reference to FIG. 3. In principle the cavities 108 could be formed using a “one-step” method having only one step of removing material from the layer structure, with sufficient material being removed from the layer structure in that one step to form cavities that extend from the surface of the layer structure at least through the active region. (This may be done, for example, by continuing the selective etching of the threading defects at block 301 of FIG. 3 until the resultant cavities extended through the layer 105 and through the active region.) Use of a “one-step” method might make it simpler to put the invention into effect. It is however expected that forming the cavities 108 using a “one-step” method would require more material to be removed from the layer structure than if the cavities 108 are formed using a two-step process such as the process of FIG. 3—and this would be disadvantageous in applications where it is desired to provide a light-emitting device with a high output power (such as a high-brightness LED). Where the obtained light-emitting device is intended to have a high optical output power, use of a two-step process such as the process of FIG. 3 may therefore be preferable to use of a one-step process.

As a further example, the embodiments described above are directed to removing all, or substantially all, threading dislocations in the device structure by attempting to form cavities that remove all threading dislocations (or that remove as many threading dislocations as is possible in practice). However, the invention is not limited to this. As noted above, there are three different types of threading dislocations that exist in nitride materials, namely screw, mixed and edge types. In a further embodiment of the invention, cavities may be formed coincident with threading dislocation of at least a first type, while no cavity is formed at a location where a threading dislocation of a second type is present. For example, the or each cavity 108 may be coincident with a first type of threading dislocation, that is cavities may be formed to remove all threading dislocations of a first type (eg, one of screw, mixed and edge threading dislocations) (or to remove as many threading dislocations of that one type as is possible in practice), while leaving dislocations of the other two types unaffected or substantially unaffected. This may be an advantage if only a certain type of threading dislocation is required to be removed from the LED, i.e. for example only threading dislocations with a screw component are desired to be removed from the LED structure. To effect this embodiment, the preferential etching step represented in block 301 of FIG. 3 may be arranged to form pilot cavities only at the locations of one type of threading dislocations (or at least to fowl pilot cavities preferentially at the locations of one type of threading dislocations) by careful selection of the etching parameters.

In a yet further embodiment of the invention, the cavities 108 may be coincident with two of the types of threading dislocation, that is cavities may be formed to remove all threading dislocations of two types (or to remove as many threading dislocations of the two selected types as is possible in practice), while leaving dislocations of the third type unaffected or substantially unaffected. This may be done by arranging for the etching step of block 301 of FIG. 3 to form pilot cavities only at the locations of two types of threading dislocation. (or preferentially at the locations of two types of threading dislocation). Alternatively, step 301 may be repeated twice with different etching parameters, once to pilot cavities at the locations of one type of threading dislocation and a second time to foam pilot cavities at the locations of another type of threading dislocation.

In principle, moreover, the invention is not limited to use of etching to remove material from the layer structure, and other methods of removing material from the layer structure may be used.

Moreover, while the problem addressed by this invention is described with particular reference to devices that have a density per unit area of threading dislocations of around 10⁸-10⁹ cm⁻², the invention is not limited to use with devices having this specific density per unit area of dislocations and may be applied to a device having any density per unit area of dislocations.

Some embodiments of the present invention disclose a semiconductor light-emitting device includes a substrate, a semiconductor layer structure and one or more cavities in the layer structure, no cavity may be formed at a location where no threading dislocation is present in the layer structure.

No cavity may be intentionally formed at a location where a threading dislocation of a second type is present in the layer structure. There may be more than one type of dislocation present in the layer structure (as an example, there are three different types of threading dislocations that exist in nitride materials, namely screw, mixed and edge threading dislocations) and, where the invention is applied to such a layer structure, the invention may remove all types of dislocations present in the layer structure or, alternatively, the invention may remove only dislocations of one or more selected types while leaving at least one other type of dislocation unaffected or substantially unaffected. As an example, where the invention is applied to a nitride layer structure, it may set out to remove threading dislocations of one type only, of two types only, or of all three types. This may be an advantage if only a certain type of threading dislocation is required to be removed from the layer structure. For example, where the invention is applied to a nitride layer structure it may be desired to remove only the pure screw threading dislocations, since these are believed to be the main source of reverse bias leakage in an LED (X. A. Cao et al., Journal of Crystal Growth 264 (2004) 172-177) and may also be the origin of non-radiative recombination in the active region (U. Jahn et al., Phys. Rev. B 81, 125314 (2010))—thus, removing only the pure screw threading dislocations should significantly improve the device performance while minimising the amount of material removed from the layer structure.

The or each cavity may extend into the first layer. Indeed, the or each cavity may extend completely through the first layer and into the device substrate.

The device may include an electrically non-conductive material disposed in the or each cavity.

The device may include a light-emitting diode. Alternatively, the device may include a laser diode.

No cavity may be formed at a location where no threading dislocation is present in the layer structure. Unlike the method proposed by Hsieh et al (above), material is intentionally removed from the layer structure only where a dislocation is present.

No cavity may be intentionally formed at a location where a threading dislocation of a second type is present in the layer structure.

Some embodiments of the present invention disclose a method of manufacturing the semiconductor light-emitting device, the method may include forming the layer structure over the substrate, before material is removed from the layer structure to faun the cavities.

Removing material from the layer structure may include etching the layer structure.

The method may include a first etching step of selectively etching the layer structure at the one or more locations at which a respective threading dislocation is present thereby to form a pilot cavity at the or each location. For example, use of an etching process that preferentially acts on the upper layer of the layer structure at the dislocations is a convenient way of selectively etching the layer structure only at locations at which a threading dislocation is present.

The method may include a second etching step of increasing the depth of the or each pilot cavity such that the or each cavity extends at least through the second layer and the active region. It is expected that use of a two-step process of removing material from the layer structure may result in less material being removed from the layer structure, and this is advantageous in applications where it is desired to provide a light-emitting device with a high output power (such as a high-brightness LED).

The second etching step may include etching the layer structure through a mask disposed on the surface of the layer structure.

The method may include disposing a mask layer over the surface of the layer structure, and selectively removing the mask layer at the or each location where a pilot cavity was formed in the first etching step thereby to form the mask.

The method may include depositing a layer of a resist over the surface of the layer structure; planarising the layer of resist such that only resist material deposited in the or each pilot cavity remains; depositing a mask layer over the surface of the layer structure; and performing a lift-off step to remove the resist material deposited in the or each pilot cavity and thereby form the mask.

Alternatively, the method may include disposing a mask layer selectively over the surface of the layer structure, whereby the mask layer is not disposed at the or each location where a pilot cavity was formed in the first etching step.

The mask may be an electrode layer.

The second etching step may be a dry etching step.

The method may include disposing an electrically non-conductive material in the or each cavity.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A semiconductor light-emitting device comprising:
a substrate;
a semiconductor layer structure disposed over the substrate and including a first layer disposed over the substrate, a second layer, and an active region for light emission disposed between the first layer and the second layer; and
one or more cavities in the layer structure, the or each cavity being coincident with a respective threading dislocation of at least a first type that extends generally through the layer structure, and the or each cavity extending from an upper surface of the layer structure through at least the second layer and the active region.

2. A device as claimed in claim 1 wherein no cavity is formed at a location where no threading dislocation is present in the layer structure.

3. A device as claimed in claim 1 wherein no cavity is formed at a location where a threading dislocation of a second type is present in the layer structure.

4. A device as claimed in claim 1 wherein the or each cavity extends into the first layer.

5. A device as claimed in claim 1 and comprising an electrically non-conductive material disposed in the or each cavity.

6. A device as claimed in claim 1 and comprising a light-emitting diode.

7. A device as claimed in claim 1 and comprising a laser diode.

8. A method of manufacturing a semiconductor light-emitting device having a semiconductor layer structure disposed on a substrate, the layer structure including a first layer disposed over the substrate, a second layer, and an active region for light emission disposed between the first layer and the second layer, the method comprising:
selectively removing material from the layer structure at one or more locations at which a respective threading dislocation of at least a first type is present in the layer structure so as to create a cavity in the layer structure, the cavity extending at least through the second layer and the active region.

9. A method as claimed in claim 8 wherein no cavity is formed at a location where no threading dislocation is present in the layer structure.

10. A method as claimed in claim 8 wherein no cavity is formed at a location where a threading dislocation of a second type is present in the layer structure.

11. A method as claimed in claim 8 and comprising forming the layer structure over the substrate.

12. A method as claimed in claim 8 wherein removing material from the layer structure comprises etching the layer structure.

13. A method as claimed in claim 12 and comprising a first etching step of selectively etching the layer structure at the one or more locations at which a respective threading dislocation is present thereby to form a pilot cavity at the or each location.

14. A method as claimed in claim 13 and comprising a second etching step of increasing the depth of the or each pilot cavity such that the or each cavity extends at least through the second layer and the active region.

15. A method as claimed in claim 14 wherein the second etching step comprises etching the layer structure through a mask disposed on the surface of the layer structure.

16. A method as claimed in claim 15 and comprising disposing a mask layer over the surface of the layer structure, and selectively removing the mask layer at the or each location where a pilot cavity was formed in the first etching step thereby to form the mask.

17. A method as claimed in claim 15 and comprising:
depositing a layer of a resist over the surface of the layer structure;
planarising the layer of resist such that only resist material deposited in the or each pilot cavity remains;
depositing a mask layer over the surface of the layer structure;
performing a lift-off step to remove the resist material deposited in the or each pilot cavity and thereby form the mask.

18. A method as claimed in claim 15 and comprising disposing a mask layer selectively over the surface of the layer structure, whereby the mask layer is not disposed at the or each location where a pilot cavity was formed in the first etching step.

19. A method as claimed in claim 15 wherein the mask is an electrode layer.

20. A method as claimed in claim 14 wherein the second etching step is a dry etching step.

21. A method as claimed in claim 8 and comprising disposing an electrically non-conductive material in the or each cavity.

22. A semiconductor light-emitting device formed by a method as defined in claim 8.
